(19) United States
(12) Patent Application Publication
(10) Pub. No.: US 2018/0054907 A1
(43) Pub. Date: Feb. 22, 2018

(54) Multifunctional Electronic Product Combining Structure

(71) Applicant: Qixuan ZHANG, Guangdong (CN)

(72) Inventor: Qixuan ZHANG, Guangdong (CN)

(21) Appl. No.: 15/680,221

(22) Filed: Aug. 18, 2017

(30) Foreign Application Priority Data
Aug. 19, 2016 (CN) 201610686771.X

(51) Int. Cl. H05K 7/02; H05K 5/00; H05K 5/02

(52) U.S. Cl. CPC H05K 7/023; H05K 5/0021; H05K 5/0247; H05K 5/0086

(57) ABSTRACT

The invention discloses a multifunctional electronic product combining structure which comprises more than two functional modules and conducting terminals connecting these functional modules. The multifunctional electronic product combining structure is characterized in that the functional modules are furnished with conducting interfaces matching the conducting terminals; the two ends of the conducting terminals are in detachable connecting fit with the conducting interfaces on the functional modules respectively, so that the functional modules are spliced and combined together, and electrification and communication transmission functions are served. Through matching of the conducting interfaces and the conducting terminals, splicing, electrification and communication transmission of the functional modules are realized, the functional modules can be freely combined into different electronic products for use and can be disassembled, assembled and replaced at any time and in any place, and resource sharing is realized.

### BACKGROUND OF THE INVENTION

The invention relates to electronic product combining structures, in particular to a multifunctional electronic product combining structure.

Electronic products currently on the market are used independently and are comparatively difficult to match during use, for example, a mobile power source and a mobile power source, a mobile power source and a Bluetooth loudspeaker box, a Bluetooth device and a loudspeaker box or other electronic functional products and so on are all used independently. Especially under the circumstance that multiple electronic products or functional modules need to be connected at the same time, adapters and multiple connecting wires are needed for connection, so that high complexity and great inconvenience are caused.

### BRIEF SUMMARY OF THE INVENTION

In light of the above-mentioned defects, the invention aims to provide a multifunctional electronic product combining structure. Through matching of conducting interfaces and conducting terminals, splicing and electrification, communication and communication of the functional modules are realized, the functional modules can be freely combined into different electronic products for use and can be disassembled, assembled and replaced at any time and in any place.

A technical scheme includes that the multifunctional electronic product combining structure comprises more than two functional modules and conducting terminals connecting the functional modules; the multifunctional electronic product combining structure is characterized in that conducting interfaces matched with the conducting terminals are arranged on each functional module; two ends of the conducting terminals are in detachable connecting fit with the conducting interfaces on the functional modules respectively, so that the functional modules are spliced and combined together, and electrification and communication transmission effects are realized.

Further, the functional modules can be an LED lamp module, a mobile memory module, a radio module and a fan module.

Further, the functional modules can be a mobile power source battery module, a mobile power source PCB (printed circuit board) module, a Bluetooth module, a loudspeaker box module, a wireless charging module, a charging and discharging module, a Bluetooth loudspeaker box module, an adapter module, an environment monitoring module or other electronic functional modules. All in all, various electronic component products are suitable, and the functional modules realize electrical functions of splicing, electrifying and communication transmission mainly through matching of the conducting terminals and the conducting interfaces.

Further, the mobile power source battery module comprises a mobile power source plastic shell and a mobile power source battery arranged in the mobile power source plastic shell; the mobile power source PCB module comprises a PCB plastic shell, a PCB arranged in the PCB plastic shell and interfaces arranged on the PCB. Different interface standards can be set, such as charging interfaces and USB (universal serial bus) interfaces.

Further, one of the functional modules is a power source base which comprises a shell and a battery arranged in the shell.

Further, each conducting terminal is a connector terminal of a columnar structure, and each conducting interface is a connector jack of a columnar structure; two ends of each connector terminal are in plug-type conducting connection with the connector jacks on the corresponding functional module, so that the functional modules are spliced and combined together, electrification and communication transmission effects are realized, in other words, electrical functions like electrification and communication transmission are realized through electrical connection.

Further, each function module is at least provided with more than one conducting interface.

The multifunctional electronic product combining structure has the advantages that each functional module (electronic component product) is provided with the corresponding conducting interfaces, and splicing, electrifying and communication transmission are realized through the conducting terminals, so that multiple functional modules can be freely combined into different electronic products for use to realize different functions and effects and can be disassembled, assembled and replaced at any time and in any place, and resource sharing is realized.

The multifunctional electronic product combining structure is further described below through drawing description and embodiments.

### BRIEF DESCRIPTION OF THE DRAWINGS

FIG. 1 is an integral schematic view;

FIG. 2 is a split schematic view of FIG. 1;

In the Figures: conducting terminal 1; conducting interface 2; power source base 3; shell 4; battery 5; mobile power source battery module 6; mobile power source PCB module 7; mobile power source plastic shell 8; mobile power source battery 9; PCB plastic shell 10; PCB 11; interface 12.

### DETAILED DESCRIPTION OF THE INVENTION

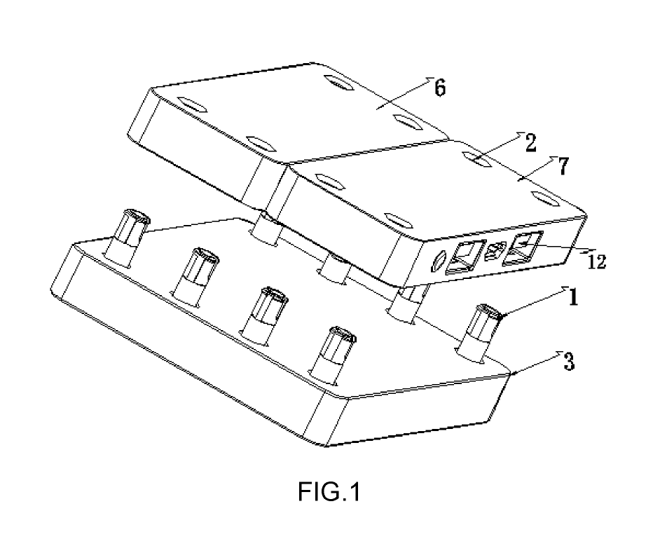

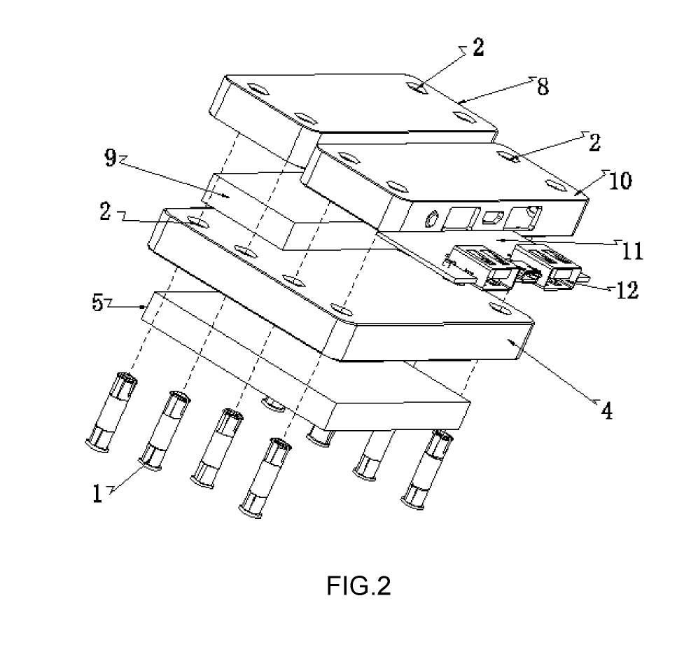

With reference to FIG. 1 to FIG. 2, the multifunctional electronic product combining structure of the embodiment comprises three functional modules and conducting terminals 1 connecting the functional modules, and each functional module is provided with conducting interfaces 2 matched with the conducting terminals 1; two ends of each conducting terminal 1 are in detachable connecting fit with the conducting interfaces 2 on the corresponding functional module respectively, so that the functional modules are spliced and combined together, and electrification and communication transmission effects are realized.

Specifically, one of the functional modules is a power source base 3 which comprises a shell 4 and a battery 5 arranged in the shell 4. The power source base 3 is provided with eight conducting interfaces 2 which are arranged in two rows and distributed equidistantly.

Specifically, other two functional modules are a mobile power source battery module 6 and a mobile power source PCB module 7, and each of the mobile power source battery module 6 and the mobile power source PCB module is provided with four conducting interfaces which are arranged in two rows and distributed equidistantly, wherein, the mobile power source battery module 6 comprises a mobile power source plastic shell 8 and a mobile power source battery 9 arranged inside the mobile power source plastic shell 8. The mobile power source PCB module 7 comprises a PCB plastic shell 10, a PCB 11 arranged in the PCB plastic shell 10 and interfaces 12 arranged on the PCB 11. Different interface standards can be set, such as charging interfaces and USB interfaces. It's necessary to note that as other embodiments, the mobile power source battery module 6 can be spliced with an LED lamp module, a mobile memory module, a radio module, a fan module, a Bluetooth module, a loudspeaker box module, a wireless charging module, a wire discharging module, a Bluetooth loudspeaker box module, an adapter module, an environment monitoring module or other electronic functional modules, for example, the mobile power source battery module 6 can be spliced with the Bluetooth loudspeaker box module through the conducting terminals 1 to form a mobile Bluetooth loudspeaker box with a power source; the mobile power source battery module 6 can be spliced with the environment monitoring module through the conducting terminals 1 to form a mobile environment detector with a power source; multiple modules can be spliced to form multifunctional electronic products.

Specifically, each conducting terminal 1 is a connector terminal of a columnar structure, and each conducting interface is a connector jack of a columnar structure; two ends of each connector terminal are in plug-type conducting connection with the connector jacks on the corresponding functional module, so that the functional modules are spliced and combined together, electrification and communication transmission effects are realized, in other words, electrical functions like electrification and communication transmission are realized through electrical connection. It's necessary to note that there are various modes of plug-type conducting connection, for example, two ends of each conducting terminal 1 are respectively plugged into the corresponding conducting interfaces 2; for another example, one conducting terminal 1 penetrates the conducting interface 2 of one functional module from the bottom of the conducting interface 2 of the functional module and then is plugged into the conducting interface 2 of another functional module.

Compared with the prior art, the multifunctional electronic product combining structure mainly has the advantages that the conducting interfaces and the conducting terminals matched with the conducting interfaces are designed, and various functional modules can be spliced and combined by the conducting interfaces and the conducting terminals to realize effects of electrification and communication, wherein each conducting interface comprises an anode connected with an electrode, a cathode connected with the electrode, D+ connected with communication and D− connected with communication, all in all, all conducting interfaces have effects of splicing and combining the functional modules and electrical functions of electrification and communication, each functional module (electronic component product) is at least provided with more than one conducting interface, and then functions of splicing, combining, electrification and communication of all functional modules are realized through the conducting terminal similar to conducting columns.

The invention is not limited to the above embodiments. Other multifunctional electronic product combining structures obtained by adopting technical features identical with or similar to the above embodiments are all within the protection range of the invention.

What is claimed is:

1. A multifunctional electronic product combining structure comprises more than two functional modules and conducting terminals connecting the functional modules; the multifunctional electronic product combining structure is characterized in that conducting interfaces matched with the conducting terminals are arranged on the functional modules; two ends of the conducting terminals are in detachable connecting fit with the conducting interfaces on the functional modules respectively, so that the functional modules are spliced and combined together, and electrification and communication transmission effects are realized.

2. The multifunctional electronic product combining structure according to claim 1 is characterized in that the functional modules can be a mobile power source battery module, a mobile power source PCB (printed circuit board) module, a Bluetooth module, a loudspeaker box module, a wireless charging module, a charging and discharging module, a Bluetooth loudspeaker box module, an adapter module, an environment monitoring module or other electronic functional modules.

3. The multifunctional electronic product combining structure according to claim 1 is characterized in that the functional modules can be an LED lamp module, a mobile memory module, a radio module and a fan module.

4. The multifunctional electronic product combining structure according to claim 2 is characterized in that the mobile power source battery module comprises a mobile power source plastic shell and a mobile power source battery arranged in the mobile power source plastic shell; the mobile power source PCB module comprises a PCB plastic shell, a PCB arranged in the PCB plastic shell and interfaces arranged on the PCB.

5. The multifunctional electronic product combining structure according to claim 1 is characterized in that one of the functional modules is a power source base which comprises a shell and a battery arranged in the shell.

6. The multifunctional electronic product combining structure according to claim 1 is characterized in that each conducting terminal is a connector terminal of a columnar structure, and each conducting interface is a connector jack of a columnar structure; two ends of each connector terminal are in plug-type conducting connection with the connector jacks on the corresponding functional module, so that the functional modules are spliced and combined together, and electrification and communication effects are realized.

7. The multifunctional electronic product combining structure according to claim 1 is characterized in that each functional module is at least provided with one conducting interface.
